(19) United States
(12) Patent Application Publication
(10) Pub. No.: US 2010/0315797 A1
(43) Pub. Date: Dec. 16, 2010

(54) Display Device

(76) Inventor: Kenji Nonaka, Fukaya-shi (JP)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/862,478

(22) Filed: Aug. 24, 2010

Related U.S. Application Data
(63) Continuation of application No. 12/242,572, filed on Sep. 30, 2008, now abandoned.

(30) Foreign Application Priority Data
Nov. 14, 2007 (JP) 2007-295487

(51) Int. Cl. H05K 1/14

(52) U.S. Cl. 361/784; 361/748

(57) ABSTRACT

According to one embodiment, a display device includes an assembly of a frame and a sub frame provided on a rear side of a display panel, and respective circuit boards provided inside the frame and the sub frame.

### CROSS-REFERENCE TO RELATED APPLICATIONS

This application is a continuation application and claims the benefit of priority on U.S. patent application Ser. No. 12/242,572, filed Sep. 30, 2008 and is based upon and claims the benefit of priority from Japanese Patent Application No. 2007-295487, filed Nov. 14, 2007, the entire contents of which are incorporated herein by reference.

### BACKGROUND

1. Field

One embodiment of the present invention relates to a display device of a flat-panel structure, such as a liquid crystal display or plasma display.

2. Description of the Related Art

A display device including a chassis member provided on the reverse side of a display panel is known as a display device of a flat-plane structure, such as a liquid crystal display or plasma display. It is disclosed by, for example, Jpn. Pat. Appln. KOKAI Publication No. 2007-199705 (see, in particular, paragraph [0038], and FIG. 8).

The chassis member for display devices disclosed in the publication comprises a base plate formed of three base-metal plates arranged on the rear side of the display panel, a metal frame superposed on the metal plates to couple them, and a plurality of ribs superposed on the metal frame to vertically and horizontally reinforce the base plate. Three vertically extending ones of the ribs have, at their upper ends, hanging tools for enabling the display device to be hung and transported.

In general, flat display devices of this type include a circuit board with a plurality of electronic components mounted on the rear side of a display panel. Therefore, when a plurality of metal members are superposed on each other thicknessways like the disclosed chassis member, if a circuit board is further superposed on the metal members, the display device becomes thick. Further, since the chassis member is formed of metal plates superposed on each other, the display device is inevitably heavy.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a perspective view illustrating the appearance of a display device according to one embodiment of the invention;

FIG. 2 is a perspective rear view illustrating a state in which the rear panel of the display device shown in FIG. 1 is removed;

FIG. 3 is a rear view illustrating an assembly of the frame of FIG. 2 and a sub frame;

FIG. 4 is a rear view illustrating a state in which the assembly of FIG. 3 is attached to the rear side of the display panel of the display device; and

FIG. 5 is a sectional view taken along line V-V in FIG. 4.

### DETAILED DESCRIPTION

One embodiment according to the invention will be described hereinafter with reference to the accompanying drawings. In general, according to the one embodiment of the invention, a display device 100 comprises an assembly of a frame 10 and sub frame 30 provided on the rear side of a display panel 102, a circuit board 41 provided in the frame 10, and another circuit board 42 provided in the sub frame 30.

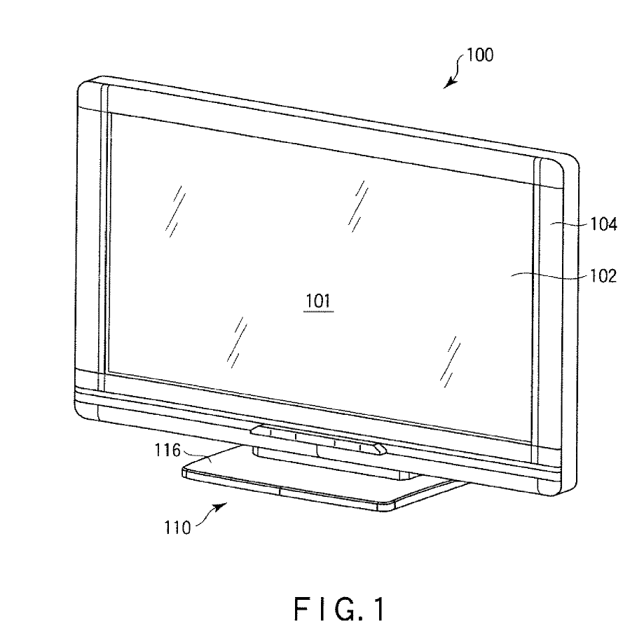

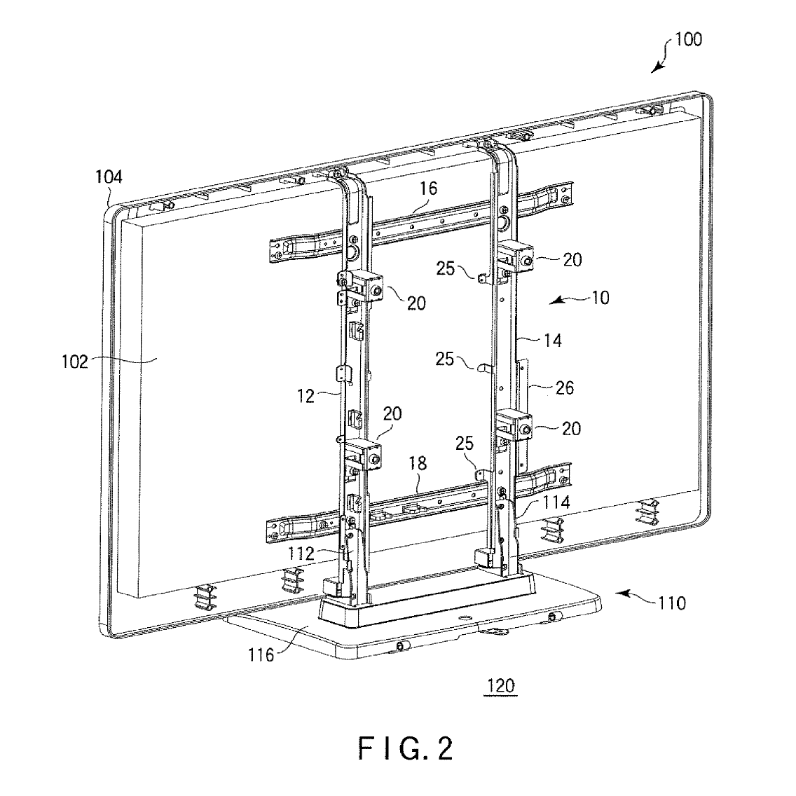

FIG. 1 shows, viewed diagonally from the front, a display device 100 according to one embodiment of the invention, i.e., a flat display device 100 such as a liquid crystal display or plasma display. FIG. 2 shows, viewed diagonally from behind, a state in which the rear cover of the display device 100 is removed.

As shown in FIGS. 1 and 2, the display device 100 comprises a rectangular flat display panel 102 having a front display surface 101, a frame-like front cover 104 covering the front-side periphery of the display panel 102, a frame 10 secured to the rear side of the display panel 102, a support stand 110 secured to the lower end of the frame 10, and a rear cover (not shown) attached to the rear side of the display panel 102 to cover the frame 10 and the fixing portion of the support stand 110.

The frame 10 according to the embodiment comprises two vertical frame members 12 and 14 extending vertical and parallel to each other, and two horizontal frame members 16 and 18 extending horizontal, parallel to each other, and coupled to the frame members 12 and 14 like a pound sign.

Each of the frame members 12, 14, 16 and 18 is formed by bending a metal strip and forming holes therein, and has ribs formed by bending its opposite ends through substantially 90°. The ribs provided at the opposite ends of each frame member increase its bending strength.

The two horizontal frame members 16 and 18 are secured to the rear side of the display panel 102 by screwing their opposite ends thereto. Similarly, the two vertical frame members 12 and 14 are secured to the front cover 104 by screwing their opposite ends to the rear side of the front cover 104, such that they bridge the horizontal frame members 16 and 18. Further, the frame members 12, 14, 16 and 18 are screwed to the rear side of the display panel 102 at four positions at which the horizontal frame members overlap the vertical frame members.

Furthermore, four wall-hanging members 20 (hereinafter referred to simply as “members 20”) for hanging the display device 100 on a wall are attached to the middle portions of each of the two vertical frame members 12 and 14. The height of each member 20 is designed so that only the four members 20 are exposed on the rear side of the display device 100 when the frame 10 is covered.

The distance between the two vertical frame members 12 and 14 is designed so that the four members 20 will be aligned with attachment holes (not shown) formed in a wall-side attachment fitting (not shown). In contrast, the vertical distance between the upper and lower ones of the members 20 can be arbitrarily changed by vertically changing the attachment positions of the vertical frames 12 and 14 on the attachment fitting. Although the distance between the two vertical frame members 12 and 14 may be arbitrarily determined in view of the length of the display panel, if it is set equal to a so-called VESA pitch, the design of the wall-side attachment fitting can be generalized advantageously.

Stand members 112 and 114 incorporated in a support stand 110 are secured to the lower ends of the two vertical frame members 12 and 14. The support stand 110 of the embodiment comprises the two stand members 112 and 114, a mount table 120 for mounting the display device 100, and a stand cover 116. Each of the stand members 112 and 114 is substantially T-shaped. More specifically, each of the stand members 112 and 114 is formed of a first member (not shown) extending parallel to the mount table 120, and a second member projecting from the middle portion of the first member. The stand cover 116 covers and fixes the first members of the stand members 112 and 114, with the second members thereof inserted through the cover. Namely, the distance between the two stand members 112 and 114 is set equal to that between the two vertical frame members 12 and 14.

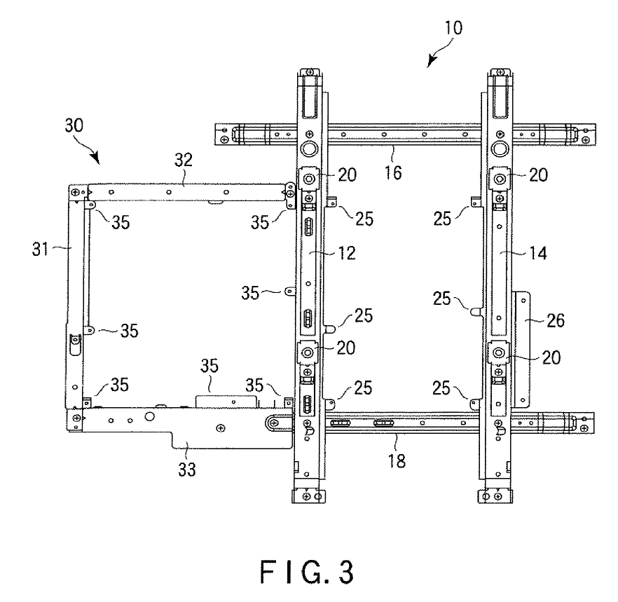

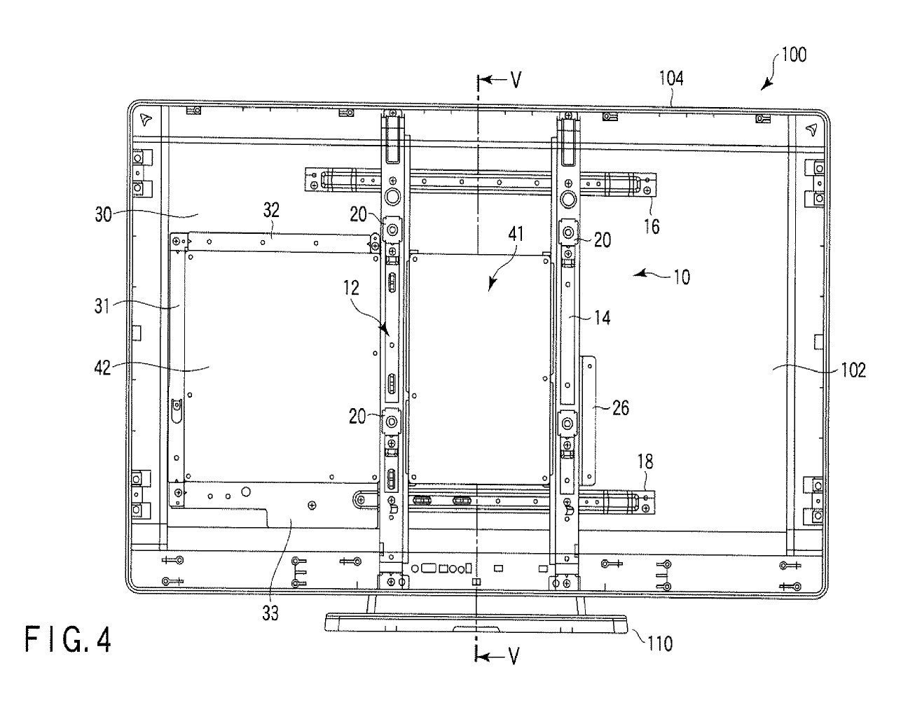

FIG. 3 shows, from behind the display device 100, an assembly in which a sub frame 30 is attached to the above-described frame 10. Although the assembly of the frames 10 and 30 is attached to the rear side of the display panel 102 as aforementioned (see FIG. 4), FIG. 3 shows only the assembly to clarify it.

The sub frame 30 includes a single vertical frame member 31 extending along the vertical axis of the display device 100, a first horizontal frame member 32 having its left end coupled to the upper end of the vertical frame member 31, and a second horizontal frame member 33 having its left end coupled to the lower end of the vertical frame member 31. Thus, the sub frame 30 is substantially U-shaped. Further, the two horizontal frame members 32 and 33 have their respective right ends coupled to the left frame member of the frame 10, i.e., the vertical frame member 12.

The coupling portions of the sub frame 30 at the four corners, namely, the opposite ends of the two horizontal frame members 32 and 33, are screwed to the rear side of the display panel 102, like the above-described horizontal frame members 16 and 18 of the frame 10. Thus, the upper end of the vertical frame member 31 and the left end of the upper horizontal frame member 32 are secured to the display panel 102 by a single screw, and the lower end of the vertical frame member 31 and the left end of the lower horizontal frame member 33 are secured to the display panel 102 by a single screw. Similarly, the right end of the upper horizontal frame member 32 and the left vertical frame member 12 of the frame 10 are secured to the display panel 102 by a single screw, and the right end of the lower horizontal frame member 33 and the vertical frame member 12 are secured to the display panel 102 by a single screw.

FIG. 4 is the rear view of the display device 100, illustrating the assembly of the frames 10 and 30 attached to the rear side of the display panel 102. Also in FIG. 4, no rear panel is shown. FIG. 4 also shows two circuit boards 41 and 42 attached to the assembly of the frames 10 and 30. More specifically, the circuit board 41 is attached to the frame 10 assembled like a pound sign, and the circuit board 42 is attached to the sub frame 30. Further, a plurality of electronic components (not shown) are mounted on both sides of each of the circuit boards 41 and 42.

One of the circuit boards attached to the frame 10, i.e., the circuit board 41, is supported and fixed by a plurality of support chips 25 (see FIG. 3) projecting from the inner edges of the two vertical frame members 12 and 14 of the frame 10. As shown in FIG. 2, the support chips 25 are projected to the rear side of the display panel 102 and bent to be substantially parallel to the rear side. Thus, the circuit board 41 is provided between the two vertical frame members 12 and 14 and between the two horizontal frame members 16 and 18, and is attached to the display panel 102 at least as close to the panel 102 as the frame 10.

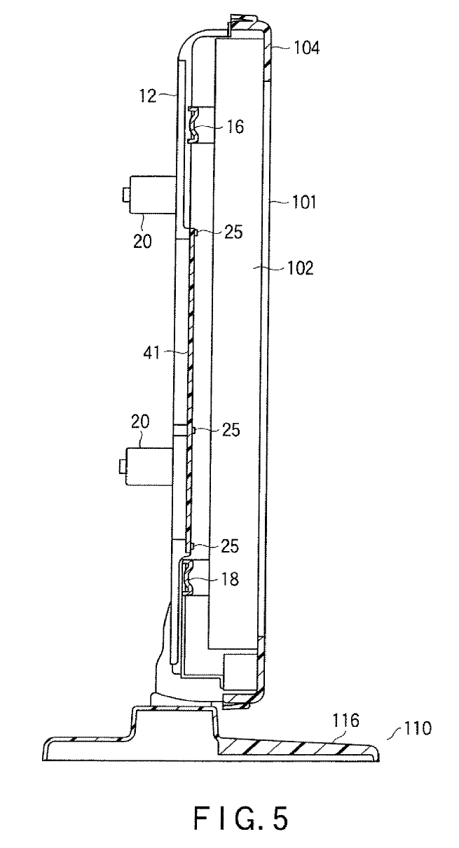

FIG. 5 is a sectional view taken along line V-V in FIG. 4. A plurality of electronic components are actually mounted on both sides of the circuit board 41, although they are not shown. In the embodiment, since the length of the support chips 25 is set so that the circuit board 41 is positioned with substantially the same distance from the display panel 102, as the distance between the panel 102 and the highest level of the horizontal frame members 16 and 18. Accordingly, the circuit board 41 is slightly closer to the display panel 102 than the vertical frame members 12 and 14.

Further, as is evident from FIG. 5, the electronic components (not shown) mounted on the circuit board 41 do not interfere the display panel 102 and also do not significantly project rearward from the frame 10. This means that the location of the circuit board 41 in the frame 10 assembled like a pound sign provides a sufficient space for allowing electronic components to be mounted on the circuit board 41, compared to the case where a circuit board is superposed on a flat frame. As a result, the circuit board 41 can be positioned closer to the display panel 102, and rearward projection of component parts from the frame 10 can be avoided, thereby thinning the display device 100.

On the other hand, the other circuit board 42 is supported and fixed by a plurality of support chips 35 projecting from the inner edges of the sub frame 30, as shown in FIG. 3. The sub frame 30 of the embodiment is attached to the frame 10 to attach the circuit board 42, and there are no constraints concerning the distance to the display panel 102. Namely, it is not always necessary to bend the support chips 35 toward the display panel 102.

However, since the circuit board 42 is also positioned within the sub frame 30 such that it does not interfere the frame members 31, 32 and 33, it can be made as closer to the display panel 102 as possible, and hence the space for containing a plurality of electronic components (not shown) mounted on the circuit board 42 can be secured.

As described above, in the embodiment, the frame 10 of the display device 100 is assembled like a pound sign, and the circuit boards 41 and 42 are supported and fixed by the support chips 35 projecting from the inner edges of the sub frame 30. This structure makes unnecessary any chassis conventionally used for attaching a circuit board, thereby reducing the weight of the display device. Further, since the frame 10 is assembled like a pound sign, the circuit board 41 can be positioned closer to the display panel 102, and hence the display device 100 can be thinned.

Furthermore, since the wall-hanging members 20 are made as members separate from the vertical frame members 12 and 14 so that they can be attached thereto and detached therefrom, a single type of frame can be used in common between display devices regardless of whether the display devices need or do not need the wall-hanging members 20. As a result, the manufacturing cost of the display devices can also be reduced.

In addition, in the embodiment, another circuit board 42 can be attached to the display panel 102 using the sub frame 30 attached to the frame 10. This enhances the degree of freedom in the layout of circuit boards. Also, the sub frame 30 does not require so high rigidity as the frame 10 that is used to reinforce the rigidity of the display device 100, which enhances the degree of freedom in designing the display device 100.

While a certain embodiment of the invention has been described, the embodiment has been presented by way of example only, and is not intended to limit the scope of the invention. Indeed, the novel method and system described herein may be embodied in a variety of other forms; furthermore, various omissions, substitutions and changes in the form of the method and system described herein may be made without departing from the spirit of the invention. The accompanying claims and their equivalents are intended to cover such forms or modifications as would fall within the scope and spirit of the invention.

For instance, although in the above-described embodiment, the circuit board 41 is supported and fixed by a plurality of support chips 25 projecting from the inner edges of the frame 10, the invention is not limited to this, but may be modified such that a support chip 26 projecting from an outer edge of the vertical frame 14 may further be employed as shown in FIG. 2 to attach yet another circuit board (not shown). In this case, yet another frame may be attached to the right hand of the frame 10.

Further, although in the above-described embodiment, the support chips 25 of the frame 10 project from the inner edges of the vertical frame members 12 and 14, this may be modified such that the support chips project only from the horizontal frame members 16 and 18, or project from both the vertical frame members 12 and 14 and horizontal frame members 16 and 18. Similarly, the attachment positions of the support chips 35 of the sub frame 30 may be changed arbitrarily.

Furthermore, in the above-described embodiment, the horizontal frame members 16 and 18 are attached to the display panel 102, and then the vertical frame members 12 and 14 are attached outside the frame members 16 and 18. Alternatively, firstly, the vertical frame members 12 and 14 may be attached to the display panel 102, and then the horizontal frame members 16 and 18 are attached outside the frame members 12 and 14.

What is claimed is:

1. A display device comprising:
a display panel;
a plurality of first frame members extending in parallel at a distance from each other along a rear side of the display panel, each of the plurality of first frame members comprising first and second ends located inside edges of the display panel at distances therefrom, and coupled to the display panel;
a plurality of second frame members extending in parallel at a distance from each other, bridging the first frame members, and coupled to the display panel and the first frame members;
a circuit board interposed between the plurality of first frame members and the plurality of second frame members, and attached to at least one of the first frame members and the second frame members; and
a plurality of support chips projecting from edges of at least one of the first frame members and the second frame members toward the display panel and being arranged for coupling to an edge of a surface of the circuit board on a display panel side to support the circuit board near the display panel.

2. A display device comprising:
a display panel;
a plurality of first frame members arranged at a distance from each other along a rear side of the display panel and coupled to the display panel;
a plurality of second frame members arranged at a distance from each other, bridging the first frame members, and coupled to the display panel and the first frame members;
a circuit board interposed between the plurality of first frame members and the plurality of second frame members, and attached to at least one of the first frame members and the second frame members; and
a plurality of support chips projecting from at least one of the first frame members and the second frame members toward the display panel, the plurality of support chips being arranged to come into contact with an edge of a surface of the circuit board on a display panel side so as to support and secure the circuit board.

3. The display device according to claim 2, further comprising a sub frame provided along the rear side of the display panel and attached to the at least one of the first frame members and the second frame members, wherein another circuit board is attached inside the sub frame in such a manner that said another circuit board does not overlap the circuit board.

4. The display device according to claim 3, wherein the sub frame includes a plurality of support chips coupled to inner edges thereof for supporting said another circuit board.

5. The display device according to claim 2, wherein the plurality of second frame members include wall-hanging members attached thereto.

6. The display device according to claim 2, wherein an end portion for each of the plurality of second frame members is coupled to a stand member incorporated in a support stand.

7. The display device according to claim 2, wherein both ends of the plurality of second frames are coupled to a front cover provided on a front side of the display panel.

8. A display device comprising:
a display panel;
a plurality of frame members coupled to the display panel;
a support portion extended from at least one of the plurality of frame members toward the display panel; and
a circuit board supported by the support portion and arranged between the plurality of frame members.

9. The display device according to claim 8, further comprising a sub frame attached to at least one of the plurality of frame members, wherein another circuit board is attached inside the sub frame in such a manner that said another circuit board does not overlap the circuit board.

10. The display device according to claim 9, wherein the sub frame includes a support chip coupled to inner edge thereof for supporting said another circuit board.

11. The display device according to claim 8, wherein the plurality of frame members include wall-hanging members attached thereto.

12. The display device according to claim 8, wherein an end portion for each of the plurality of frame members is coupled to a stand member incorporated in a support stand.

13. The display device according to claim 8, wherein both ends of the frame members are coupled to a front cover provided on a front side of the display panel.
